(19) United States
(12) Patent Application Publication
(10) Pub. No.: US 2008/0017875 A1
(43) Pub. Date: Jan. 24, 2008

(54) Yellow Emitting Phosphor And White Semiconductor Light Emitting Device Incorporating The Same

(75) Inventors: Dong-Yeoul Lee, Busan-city (KR); Yong-Tae Kim, Jeonju-city (KR); Eun-Joung Kim, Buk-Jeju-do (KR)

Correspondence Address: CONLEY ROSE, P.C.;David A. Rose, P. O. BOX 3267, HOUSTON, TX, 77253-3267, US

(73) Assignee: LUXPIA CO., LTD., Wanju-city, (KR)

(21) Appl. No.: 10/596,804

(22) PCT Filed: Dec. 30, 2003
(86) PCT No.: PCT/KR03/02897

§ 371 Date: Apr. 20, 2007

(30) Foreign Application Priority Data
Dec. 23, 2003 (KR) 1020030095821

(51) Int. Cl. H01L 33/00; C09K 11/08

(52) U.S. Cl. 257/98; 423/263

(57) ABSTRACT

The present invention relates to a yellow phosphor represented by a general formula of A(_{1-y})₃D₅₋ₓ Eₓ O₁₂:Ce_{y} (wherein: A is at least one element selected from the group consisting of Y, Lu, Sc, La, Gd and Sm; D is at least one element selected from the group consisting of Al, Ga and In; E is at least one element selected from the group consisting of B and Fe; 0≦x<0.5; and 0.0001≦y<0.5), and a white semiconductor light emitting device incorporating the same. The white semiconductor light emitting device comprises a semiconductor light emitting diode, and a phosphor coating layer. The phosphor coating layer comprises yellow phosphor and optionally zinc selenium-based red phosphor that absorb a portion of light emitted by the semiconductor light emitting diode and emits light of wavelength different from that of the absorbed light and a transparent resin. The white semiconductor light emitting device has excellent color rendering and experiences only extremely low degrees of deterioration in emission efficiency in a long period of service.

### BACKGROUND OF THE INVENTION

(a) Field of the Invention

The present invention relates to a semiconductor light emitting device. More particularly, it relates to a yellow phosphor and a semiconductor light emitting device incorporating the yellow phosphor which absorbs a portion of light emitted by a light emitting diode, and emits light of a wavelength different from that of the absorbed light, thereby implementing such white light as purely white light and bluish white light by incorporating the yellow phosphor.

(b) Description of the Related Art

A semiconductor light emitting diode (LED) is a PN-junctioned compound semiconductor. It is a kind of optoelectronic device that emits light energy corresponding to the band gap of a semiconductor generated by a combination of an electron and a hole when a voltage is applied.

As full colorization of an LED was realized with the development of a high luminance blue LED using a GaN-based nitride as the semiconductor luminescent material, application of LEDs has expanded from display devices to illumination devices). LEDs for lighting applications offer about 10 to 15% less power consumption compared with conventional illumination devices such as fluorescent bulbs and incandescent bulbs, a semi-permanent life of over 100,000 hours, and environmental friendliness. Thus, they can significantly improve energy efficiency.

For using a semiconductor luminescent element for an illumination device, white light should be obtainable using LEDs. Largely, three methods of fabricating white semiconductor light emitting diode have been used. One of them obtains white light by combining three LEDs emitting red, green and blue colors, respectively. In this method, an InGaN or AlInGaP phosphor is used as a luminescent material. According to this method, it is difficult to construct a white LED by combining three RGB LEDs on a single chip, and also to control a current strength because each LED is made from different material by different method, and the driving voltage of each LED is different. In another method, a UV LED is used as a light source to excite three-color (RGB) phosphor to obtain white light. It uses an InGaN/R,G,B phosphor as a luminescent material. This method is applicable under a high current and improves color sensation. However, the above two methods have the following problems: a suitable material to obtain green light has not been developed as yet; and light emitted from the blue LED may be absorbed by the red LED to lower the overall light emitting efficiency. As an alternative method, a blue LED is used as a light source to excite a yellow phosphor to obtain white light. In general, an InGaN/YAG:Ce phosphor is used as a luminescent material in this method.

When the illumination device uses phosphor, its emitting efficiency increases as a difference in wavelengths of an exciting radiation and an emitted radiation gets small. Thus, the light emitting characteristic of a phosphor plays a very important role in determining the color and luminance of a semiconductor light emitting device when incorporated therein. Generally, a phosphor includes a matrix made of a crystalline inorganic compound, and an activator that converts the matrix into an effective fluorescent material. The phosphor emits light mainly in the visible wavelength region when an electron excited by absorbing a variety of forms of energy returns to its ground state. The color of emitted light can be adjusted by controlling the combination of the matrix and activator.

Examples of white semiconductor light emitting devices are disclosed in many documents.

U.S. Pat. Nos. 5,998,925 and 6,069,440 (Nichia Kagaku Kogyo Kabushiki Kaisha) disclose a white semiconductor light emitting device using a nitride semiconductor, which comprises a blue light emitting diode containing the nitride semiconductor represented by the formula: InᵢGaⱼAlₖN (0≦i, 0≦j, 0≦k, i+j+k=1) and a yellow phosphor containing a YAG (yttrium, aluminum, garnet)-based garnet fluorescent material that absorbs a portion of light emitted from the blue light emitting diode and emits light of wavelength different from that of the absorbed light. For the YAG-based phosphor, a mixture of a first phosphor, Y₃(Al₁₋ₛGaₛ)₅O₁₂:Ce, and a second phosphor, RE₃Al₅O₁₂:Ce, (0≦s≦1; RE is at least one of Y, Ga and La) are used.

U.S. Pat. No. 6,504,179 (Osram Optosemiconductors GmbH) discloses a white-emitting illuminating unit using a BYG approach (combination of blue, yellow and green) instead of the conventional RGB approach (combination of red, green and blue) or BY approach (combination of blue and yellow). This white-emitting illumination unit comprises an LED emitting a first light in the range of 300 nm to 470 nm as a light source, and the first light is converted into light of longer wavelength by the phosphor exposed to the first light. To aid the conversion, an Eu-activated calcium magnesium chlorosilicate-based green phosphor and a Ce-activated rare earth garnet-based yellow phosphor are used. For the Ce-activated rare earth garnet-based yellow phosphor, a phosphor represented by the formula RE₃(Al, Ga)₅O₁₂:Ce (RE is Y and/or Tb), at least 20% of the total emission of which lies in the visible region of over 620 nm, is used.

U.S. Pat. No. 6,596,195 of General Electric discloses a phosphor which is excitable between the near UV and blue wavelength region (ranging from about 315 nm to about 480 nm) and has an emission peak between the green to yellow wavelength region (ranging from about 490 nm to about 770 nm), and a white light source incorporating the same. This phosphor has a garnet structure and is represented by the formula: (Tb_{1-x-y}AₓRE_{y})₃D_{z}O₁₂ (where: A is selected from the group consisting of Y, La, Gd and Sm; RE is selected from the group consisting of Ce, Pr, Nd, Sm, Eu, Gd, Dy, Ho, Er, Tm, Yb and Lu; D is selected from the group consisting of Al, Ga and In; A is selected such that A is different from RE; x is in the range from 0 to 0.5; y is in the range from 0.0005 to 0.2; and z is in the range from 4 to 5).

As described above, conventional white semiconductor light emitting devices excite YAG-based yellow phosphors to emit light mainly using UV LEDs or blue LEDs and obtain white light with a combination thereof. However, the YAG-based yellow phosphor emits yellowish green light, and if other materials are added in place of yttrium and aluminum to cause a change in emitted light toward a longer wavelength, the emitting luminance is reduced.

### SUMMARY OF THE INVENTION

Thus, an object of the present invention is to solve the problems described above, and provide a phosphor that can improve the emitting luminance and color rendering of a white light emitting device and a white semiconductor light emitting device which experiences only extremely low degrees of deterioration in emission intensity, emission efficiency and color shift over a long period of service and implements a wide range of colors.

### BRIEF DESCRIPTION OF THE DRAWINGS

FIG. 1 is a graph showing an absorption spectrum and emission spectrum of borate-based yellow phosphor in accordance with one embodiment of the present invention.

FIG. 2 is a graph showing an emission spectrum depending on the amount of boron in borate-based yellow phosphor in accordance with one embodiment of the present invention.

FIG. 3 is a graph showing an emission spectrum of white light emitting diode combining a blue LED with borate-based yellow phosphor in accordance with one embodiment of the present invention.

FIG. 4 is a graph showing absorption spectrum and emission spectrum of zinc selenium-based red phosphor in accordance with another embodiment of the present invention.

FIG. 5 is a graph showing emission spectrum of pink light emitting diode combined blue LED with zinc selenium-based red phosphor in accordance with another embodiment of the present invention.

FIG. 6 is a color coordinate representing the range of color reproduction obtained by the light emitting diode combined blue LED with borate-based yellow phosphor and zinc selenium-based red phosphor in accordance with another embodiment of the present invention.

FIG. 7 is a schematic view of a lead type white semiconductor light emitting device incorporating borate-based yellow phosphor and zinc selenium-based red phosphor in accordance with the present invention, and a partial enlarged sectional view thereof.

FIG. 8 is a schematic view of a double mold type white semiconductor light emitting device, and a partial enlarged sectional view thereof.

FIG. 9 is a schematic view of a surface mount type white light emitting device of the reflector injection type incorporating borate-based yellow phosphor and zinc selenium-based red phosphor in accordance with another embodiment of the present invention.

FIG. 10 is a schematic view of a surface mount type white light emitting device of the reflector injection and double mode structure.

FIG. 11 is a sectional view of a surface mount type white light emitting device of the PCB type incorporating borate-based yellow phosphor and zinc selenium-based red phosphor in accordance with another embodiment of the present invention.

### DESCRIPTION OF THE REFERENCE NUMBER OF IN THE DRAWINGS

| | |
|---|---|
| 3, 10, 20: LED chip | 4, 11, 22: anode lead |
| 5, 12, 21: cathode lead | |
| 6, 6a, 13, 13a, 23: phosphor coating layer | |
| 6b, 13b: transparent material layer | 8: phosphor particle |
| 9, 17: recess portion | 16: casing |
| 25: PCB layer | 15, 26: molding layer |

### DETAILED DESCRITPION OF THE PREFERRED EMBODIMENTS

In one aspect, the present invention provides a yellow phosphor represented by the following chemical formula 1:
A_{(1-y)3}D₅₋ₓEₓO₁₂:Ce_{y} Chemical Formula 1

In the formula, A is at least one element selected from the group consisting of Y, Lu, Sc, La, Gd and Sm; D is at least one element selected from the group consisting of Al, Ga and In; E is at least one rare element selected from the group consisting of B and Fe; 0≦x<5; and 0.0001≦y<0.5.

The shape of phosphor is not limited particularly, but preferably is polygonal, spherical, or flaked, and more preferably is spherical phosphor having a mean diameter of 100 nm to 50 μm.

The yellow phosphor has an absorption peak at about 420 nm to 480 nm of wavelength, and an emission peak at about 510 nm to 570 nm of wavelength.

In another aspect, the present invention further provides a white semiconductor light emitting device comprising a semiconductor light emitting diode, and a phosphor coating layer comprising a yellow phosphor, which absorbs a portion of light emitted from the semiconductor light emitting diode and emits light of wavelength different from that of the absorbed light, and a transparent resin, wherein the yellow phosphor comprises a yellow phosphor represented by chemical formula 1.

In the semiconductor light emitting device, the main emission spectrum peak lies in the range from 400 nm to 530 nm. Preferably, the main emission wavelength of the yellow phosphor is longer than the main peak wavelength of the semiconductor light emitting diode.

The thickness of the phosphor coating layer (T₁) and the thickness of the semiconductor light emitting device (T₂) meet preferably the equation, T₂<T₁≦3T₂, and more preferably 1.5 T₂<T₁≦2.5 T₂.

The shape of yellow phosphor in the phosphor coating layer is not limited, but is preferably polygonal, spherical, or flaked, and more preferably spherical, with a mean diameter of 0.1 to 50 μm.

The yellow phosphor in phosphor coating layer contains preferably 0.01 to 10 wt % of phosphor particles having a mean diameter of less than 1 μm, and 90 to 99.9 wt % of phosphor particles having a mean diameter of 1 to 50 μm. The yellow phosphor can be a mixture of phosphor represented by chemical formula 1 and conventional yellow phosphors such as (YGd)₃(AlGa)₅O₁₂:Ce, or Tb₃Al₅O₁₂:Ce.

The phosphor coating layer further comprises zinc selenium (ZnSe)-based red phosphor. Preferably, the zinc selenium-based red phosphor is mixed in the amount of 10 to 40 wt % based on the weight of the yellow phosphor.

The semiconductor light emitting device comprises a substrate and a nitride semiconductor layer. The substrate is made from sapphire (Al₂O₃) or silicone carbide (SiC), the nitride semiconductor layer comprises a GaN, InGaN, or InGaAlN semiconductor.

In another aspect, lead type white semiconductor light emitting device and surface mount type light emitting type white semiconductor light emitting device with various structures are provided.

The white semiconductor light emitting device can be used for backlight in a liquid crystal device (LCD).

Hereinafter, the present invention is described in more detail.

The yellow phosphor provided by the present invention is represented by the following chemical formula 1:
A_{(1-y)3}D₅₋ₓEₓO₁₂:Ce_{y} Chemical Formula 1

In the formula, A is at least one element selected from the group consisting of Y, Lu, Sc, La, Gd and Sm; D is at least one element selected from the group consisting of Al, Ga and In; E is at least one element selected from the group consisting of B and Fe; 0≦x<5; and 0.0001≦y<0.5.

In the chemical formula, a desirable light emission efficiency, luminance, and good maintenance of activator function can be obtained when x and y are in the described ranges.

In the formula, A is a mixture of Y and Gd, the mixing mole ratio of which can be adjusted.

The yellow phosphor has an absorption peak at about 420 nm to 480 nm and an emission peak at about 510 nm to 570 nm.

The shape of phosphor is not limited, but preferably is polygonal, spherical, or flaked. More preferably, it is spherical phosphor having a mean diameter of 100 nm to 50 μm, preferably 100 nm to 30 μm.

Examples of the yellow phosphor are Y_{2.99}Al₂B₃O₁₂:Ce_{0.01}, Y_{2.99}Al₄BO₁₂:Ce_{0.01}, and (YGd)_{2.99}Al₂B₃O₁₂:Ce_{0.01}.

The yellow phosphor according to the present invention can be prepared by several methods known to one of ordinary skilled in the art, including the solid phase method, liquid phase method, and gas phase method. Among the preparation methods, the spray pyrolysis which is a kind of gas phase method is preferable to produce the nano-sized phosphor particles. When preparing the nano-sized yellow phosphor using the spray pyrolysis, the phosphor has improved luminescent property despite of narrow particle distribution. This is what causes a surface defect of phosphor caused in the ball milling process to reduce the particle size of the solid phase method, to lower the luminance. Because phosphor particles prepared by spray pyrolysis are alone or are divided into several particles through re-crystallization, the luminance is not reduced. The phosphor particles prepared by ultrasonic spray pyrolysis have a mean diameter of 100 nm to 10 μm.

In the preparation of phosphor powder according to the present invention, the phosphor structure may become different depending on a metal compound for forming the phosphor matrix and a metal compound doped into the matrix. All modification of the component and its amount made by an ordinary skilled person in the art fall within the present invention as long as the component is represented by chemical formula 1, and amount thereof falls with the scope of the present invention.

Preparation of a phosphor by the gas phase method will be described in detail.

In the gas phase method, a phosphor is prepared by three steps of: (1) preparing a precursor solution by dissolving a nitrate compound of component element constituting the yellow phosphor represented by chemical formula 1, and boric acid or iron nitrate in a solvent; (2) supplying the precursor solution to a spraying unit to form droplets; and (3) drying, pyrolyzing and heat treating the droplets using a spraying and pyrolyzing unit.

Each step of the preparation of a phosphor will be described as below.

<Step 1: Preparation of Spray Solution >

In preparing a precursor spray solution to obtain a phosphor powder, at least one element selected from the group consisting of Y, Lu, Sc, La, and Gd, at least one element selected from the group consisting of Sm, Al, Ga and In, and boron compound, or iron compound, etc. are used for preparing a phosphor powder matrix, and a cerium compound is used for preparing an activator to dope into the matrix. Water or alcohol is used as a solvent to dissolve the metal compounds for the phosphor matrix, and as the matrix metal compound, nitrates, acetates, chlorides, hydroxides or oxide forms that easily dissolve in the solvent are used.

Because the phosphor particle size is determined by the concentration of the precursor solution, the concentration of the precursor solution should be controlled to obtain particles of a desirable size. Preferably, the concentration is controlled in the range of 0.002 M to 3.0 M. If the concentration is below 0.002 M, the phosphor powder yield decreases. Otherwise, if it is over 3.0 M, the precursor solution is not sprayed well due to a solubility problem.

<Step 2: Spraying Droplets>

The obtained precursor solution is supplied to a spraying unit and sprayed as liquid droplets. It is preferable that the diameter of the liquid drop lies in the range of from 1 to 10 μm in consideration of the final phosphor particle size. For the spraying unit, an ultrasonic spraying unit, air nozzle spraying unit, ultrasonic nozzle spraying unit, etc. can be used. When an ultrasonic spraying unit is used, fine phosphor powders of sub-micron dimension can be prepared in high concentration, and when air nozzle or ultrasonic nozzle units are used, particles of micron to sub-micron dimensions can be prepared in large scale. To obtain phosphor powders, an ultrasonic liquid drop generation unit, which produces fine liquid drops having a size of several microns, is preferable.

<Step 3: Preparation of Phosphor Powder>

Fine liquid drops formed by the liquid drop generation unit are converted to phosphor particle precursors in a hot tube reactor. Preferably, the temperature of the reaction electric furnace is maintained in the range from 200 to 1,500° C., which is the range that the precursor materials can be dried and pyrolyzed. In the spraying and pyrolyzing step, the liquid drops pass through the reactor within a few seconds. Therefore, heat treatment is performed for crystal growth of the phosphor particles. This heat treatment is performed at a temperature range of 800 to 1,800° C., more preferably 1,100 to 1,300° C. for 1 to 20 hours. The heat treatment temperature may be varied depending on the phosphor.

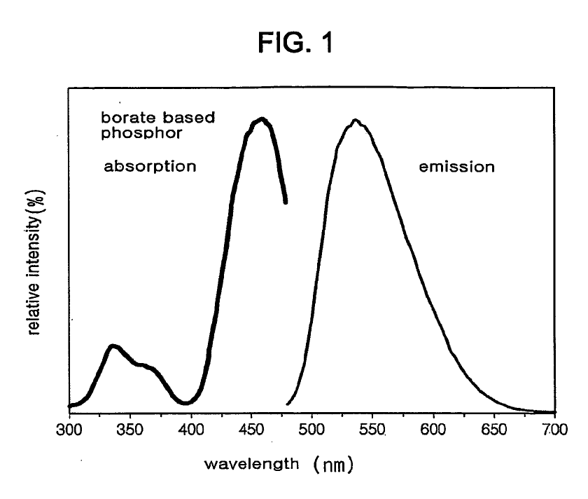

FIG. 1 is a graph showing an absorption spectrum and an emission spectrum of borate-based yellow phosphor. As shown in FIG. 1, the yellow phosphor according to the present invention has a high absorption peak at 420 nm to 480 nm, and a high emission peak at 510 nm to 570 nm.

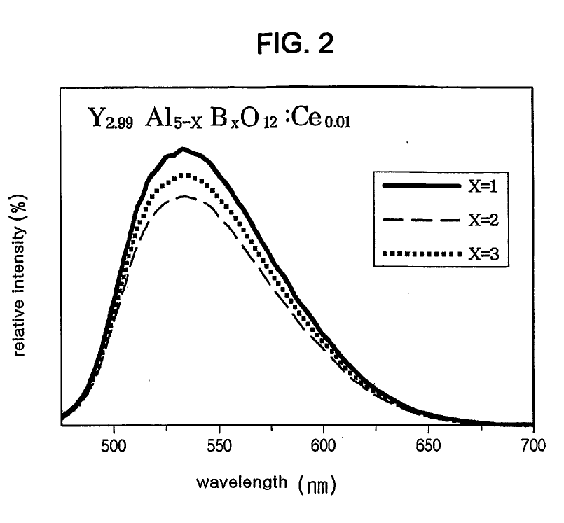

FIG. 2 represents an emission spectrum depending on the different compositions of the matrix of the phosphor. When x is 1, 2, or 3 in Y_{2.99}Al₅₋ₓBₓO₁₂:Ce_{0.01}, the phosphor has a high absorption peak at 400 nm to 470 nm, and height emission peak at around 530 nm. Such a result reported that the phosphor maintained a good emission property, even though the stoichiometrical ratio of boron increased.

Thus, the yellow phosphor can be used suitably for implementing white color by using a blue chip and applications adopting the light as an energy source.

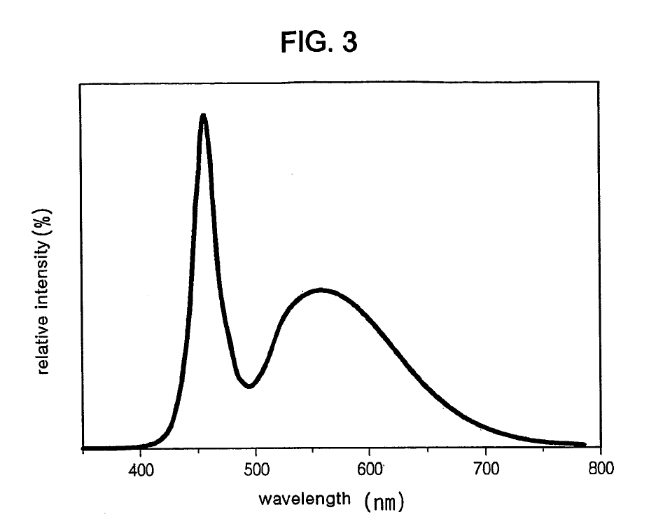

FIG. 3 represents an emission spectrum of white light emitting diode combining blue LED with borate-based yellow phosphor in accordance with one embodiment of the present invention. As shown in FIG. 3, the yellow phosphor absorbs a portion of light emitted from the blue LED chip and emits a second light of wavelength different from that of the absorbed light. Thus, the combination of the second light and the reference light produces white light.

The semiconductor light emitting device in accordance with the present invention comprises a semiconductor LED, and a phosphor coating layer including a transparent resin, and the yellow phosphor which absorbs a portion of light emitted from the blue LED and emits light of wavelength different from that of the absorbed light. The yellow phosphor is one represented by the Chemical formula 1,

The main emission spectrum peak of the LED lies in the range from 400 nm to 530 nm. Preferably, the main emission wavelength of the yellow phosphor is longer than the main peak wavelength of the nitride semiconductor.

The semiconductor LED can be a UV chip or a blue chip comprising GaN, InGaN, or AlGalnN nitride phosphor coated on sapphire, SiC, or other materials as substrates. The main emission spectrum peak of the LED lies in the range from 400 nm to 530 nm. Preferably, the main emission wavelength of the yellow phosphor is longer than the main peak wavelength of the nitride semiconductor.

The shape of yellow phosphor in the phosphor coating layer is not limited, but is preferably spherical or flaked. Preferably, the particle size of the yellow phosphor ranges from 0.1 to 50 μm.

Based on the fact that the phosphor emits light on its surface, as the particle size of the phosphor decreases, the emission intensity increases because of large surface area. However, if the particle size is excessively reduced, scattered light is absorbed by the particle, and thus disappears. Thus, to maximize the emission property of the phosphor, phosphor with the optimal particle size is needed.

The specific gravity of fluorescent material is several times as high as the coating solution before it is cured. The viscosity of thermosetting resin decreases greatly when it is cured by heat. Thus, if the LED chip is coated with liquid resin including phosphor, most of the phosphor in the resin solution tends to sediment and to congregate around the LED chip. Because only the phosphor precipitated around the LED chip absorb the emitted light effectively, most phosphor cannot convert the light emitted from LED chip, and block the light emitted by the phosphor, so as to reduce the light energy. As a result, this can reduce the emission intensity of the light emitting diode.

Considering the surface emitting property of the phosphor, in the present invention, the phosphor with the suitable particle size, shape, and distribution is used so that the phosphor can show as many light conversion as possible.

If the mean diameter of the phosphor exceeds 50 μm, a large amount of the phosphor is needed because of a low surface area. Thus, this causes light blocking and reduces the light energy at high extent. If the mean diameter of the phosphor is less than 100 nm, the light emission property decreases rapidly in the process of reducing the particle size of the preparation of the phosphor. According to one embodiment of the present invention, the amount of the phosphor with mean diameter ranging from 100 nm to 1 μm is 0.01 to 10 wt % with respect to the total amount of the phosphor, and the phosphor with mean diameter of 1 to 50 μm is the remaining amount. In addition, the color conversion layer can be formed effectively by locating the phosphor with large mean diameter in a lower part of the phosphor coating layer and the phosphor with small mean diameter in a higher part.

In consideration of the color rendering of the light emitting device, and light blocking and energy reduction caused by the phosphor, the relations between the thickness of phosphor coating layer (T1) and the thickness of the LED (T2) satisfies the formula, T₂<T₁≦3T₂, more preferably 1.5 T₂<T₁≦2.5T₂.

For the transparent resin used in the phosphor coating layer, any resin available in the art for such purpose can be used. Preferably, an epoxy resin or a silicone resin is used.

The phosphor coating layer may further comprise a zinc selenium-based red phosphor. The amount of zinc selenium-based red phosphor depends on the color range to be implemented. Preferably, the zinc selenium-based red phosphor is contained in 10 to 40 wt %, more preferably 10 to 20 wt %, based on the weight of the yellow phosphor. If the amount of the zinc selenium-based red phosphor increases, the pink light is more implemented.

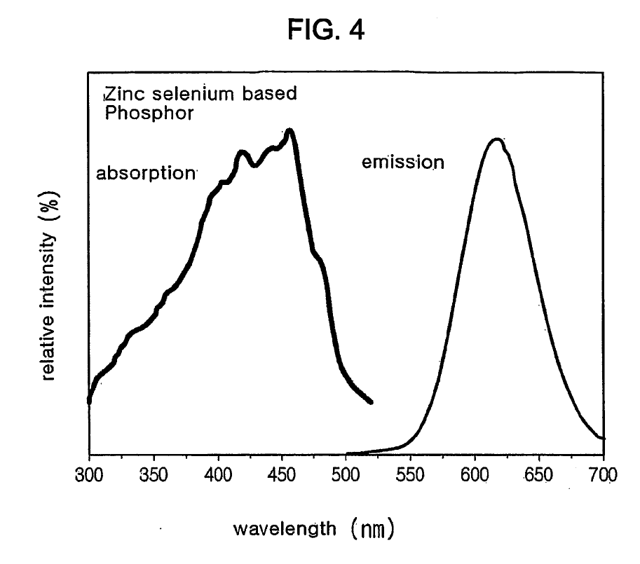

FIG. 4 shows an absorption spectrum and an emission spectrum of the zinc selenium-based red phosphor. As shown in FIG. 4, the absorption spectrum shows a high absorption peak at 400 to 530 nm region, and the emission spectrum shows a high emission peak at about 620 nm. Accordingly, the zinc selenium-based red phosphor can be effectively used for implementing red light in combination with a UV chip and pink light in combination with a blue chip, and for applications adopting the light as an energy source.

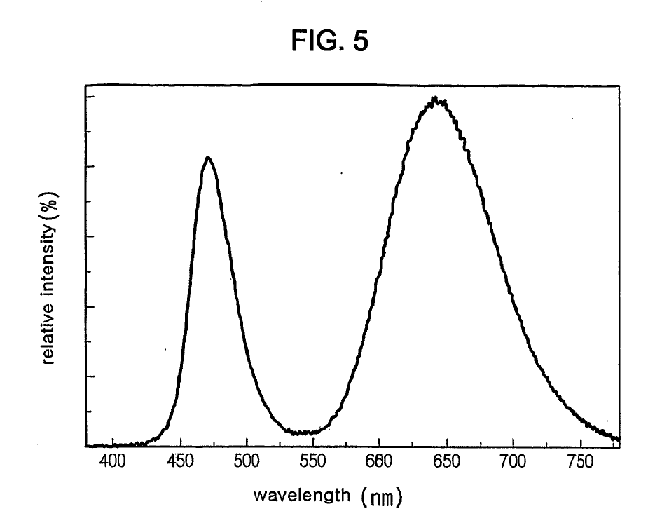

FIG. 5 shows an emission spectrum of a pink emitting diode combining a zinc selenium-based red phosphor with a blue LED. As shown in FIG. 5, the red phosphor absorbs a portion of light emitted from the blue LED chip and emits a second light of wavelength different from that of the absorbed light, thus the combination of the second light and the reference light produces white or pink light.

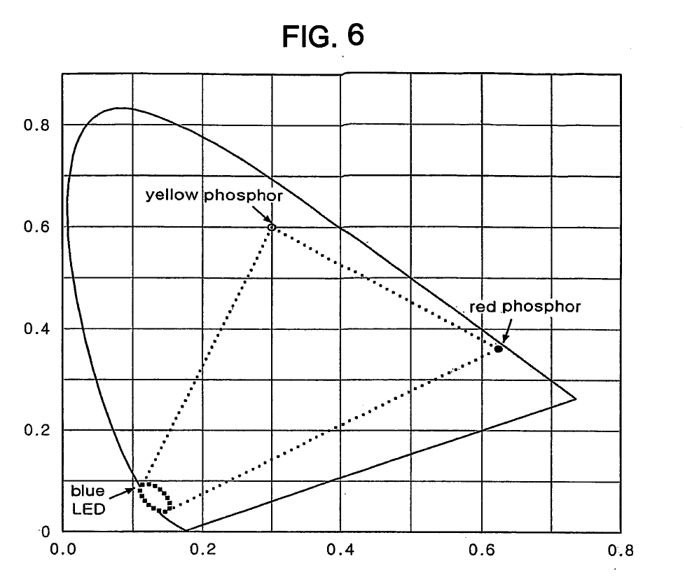

FIG. 6 is a color coordinate showing the colorization range that can be obtained by a light emitting diode combining a borate-based yellow phosphor, a zinc selenium-based red phosphor and a blue LED. As shown in FIG. 6, colors belonging to the color coordinate can be obtained by selecting the blue chip in the range from 450 to 480 nm, and controlling the mixing ratio of the terbium borate-based yellow phosphor and zinc selenium-based red phosphor.

The light emitting diode according to an embodiment of the present invention has a high energy band gap in the light emitting layer. The light emitting device is formed by combining a blue semiconductor InGaN based LED, borate-based yellow phosphor, and zinc selenium-based red phosphor. White, bluish white, pink, and pastel tone color can be implemented by a combination of blue light from the blue LED, and yellow and red color emitted from the phosphor which is excited by the light emitted from the blue LED. In addition, the white semiconductor light emitting device of the present invention offers a greatly improved color rendering and experiences less deterioration in light emission efficiency over a long period of service.

The white semiconductor light emitting device of the present invention can be fabricated in a surface mount type or a lead type during the packaging process. Such materials as metal stem, lead frame, ceramic, printed circuit board, etc. can be used for packaging. The packaging is performed to protect the device from electrical connection with outside and from external mechanical, electric and environmental factors, to offer a heat dissipation path, increase the light emission efficiency, optimize orientation, and so forth.

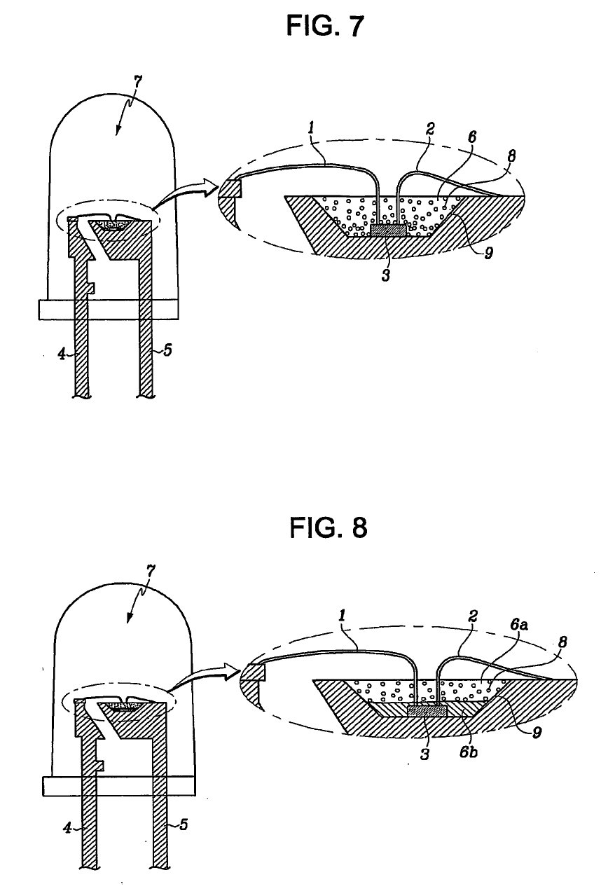

FIGS. 7 to 11 show a variety of white semiconductor light emitting device.

FIG. 7 is a schematic view of lead type white semiconductor light emitting device, and a partial enlarged sectional view thereof. The lead type white semiconductor light emitting device comprises a cup-shaped recess portion 9 on top of a lead frame, an LED chip 3 and a phosphor coating layer 6 at the recess portion 9. The LED chip 3 is connected to an anode lead 4 and a cathode lead 5 by metal wires 1, 2. A portion of the anode lead 4 and cathode lead 5 is exposed to outside and all the other components are sealed in a casing 7 made of transparent or colored light-transmitting material. The inner wall of the recess portion 9 acts as a reflection plate, and the phosphor coating layer 6 comprises yellow phosphor particles 8 and a transparent epoxy resin or silicone resin.

FIG. 8 is a schematic view of a double mold type white semiconductor light emitting device, and a partial enlarged sectional view thereof. FIG. 8 is different from the FIG. 7 in that mold material is formed in a dual-layer in the recess portion 9. That is, transparent material layer 6b, such as a silicone layer is formed to the upper part which is higher than the top of LED chip 3 in the recess portion, while covering the LED chip 3, and the phosphor coating layer 6a is formed on the transparent material layer. Considering a depth of the recess portion 9 is about 0.2-0.6 mm and a height of the blue LED chip 3 is about 100 μm, it is preferable that a thickness of the transparent material layer 6b is about 100-200 μm. The phosphor coating layer 6a is formed on the transparent material layer 6b while covering an upper portion of the recess portion 9.

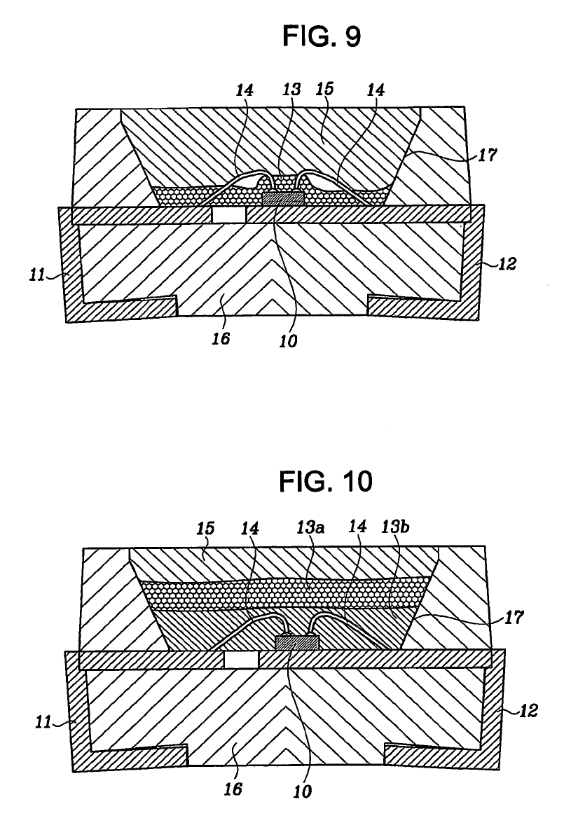

FIG. 9 is a schematic view of a surface mount type white light emitting device of the reflector injection type.

As shown in FIG. 9, the light emitting device comprises a casing 16 with recess portion 17 in its upper part, and metal ends 11, 12 which acts as the anode lead and the cathode lead. The anode and cathode lead 11 and 12 are respectively connected to N-type and P-type electrodes of the LED chip 10 by fine metal wires 14. A phosphor coating layer containing the transparent resin and phosphor particle is on the LED chip 10 disposed in an inner part of the recess portion 17. The molding layer 15 is at the same height as the top of the recess portion 17, so that the metal wire is embedded in the molding layer. The inner wall of the recess portion 17 acts as a reflective plate, and the recess portion 17 can be formed by injection molding. The phosphor coating layer includes a yellow phosphor, and can further include a red phosphor.

FIG. 10 is a schematic view of white light emitting device of the reflector injection type and double mode structure. The embodiment is different from those of FIG. 7 and FIG. 9 in that the recess portion 17 has triple mold layers. That is, a transparent material layer 13b is formed to the upper part which is higher than the top of the LED chip 10, while covering a top surface of the LED chip 10 in inner part of the recess portion 17. A phosphor coating layer 13a is formed on the transparent material layer 13b, and another transparent material layer is formed on the phosphor coating layer 13a at the same height as the top surface of the recess portion 17. The structure can be obtained by forming a transparent material layer 13b such as silicone on a bottom of the cut while covering a top surface of the LED chip 10, filling a liquid molding material containing a yellow phosphor and zinc selenium-based red phosphor on the transparent material layer to precipitate uniformly the phosphor as a phosphor coating layer 13a based on the specific gravity difference between the phosphor and molding material, forming the transparent molding layer 15 in the inner part of the recess portion 17.

According to the present invention, the white light emitting diode with high energy efficiency can be obtained by controlling the particle size of the phosphor to the be sub-micrometer, the shape and distribution of the phosphor to locate in inner part of the recess portion, and the height of the phosphor coating layer. That is, the color conversion layer is efficiently formed by distributing the phosphor particles from small particle size of sub-micrometer in the bottom to large particle size in the top of the recess portion. Thus, the white light emitting diode with the high efficiency can be obtained by controlling the thickness of the filling layer.

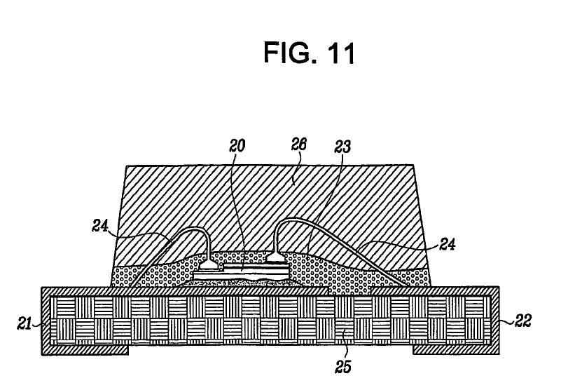

FIG. 11 is a sectional view of a surface mount type white light emitting device of the PCB type. As shown in FIG. 11, the LED chip 20 is on the PCB layer 25, and the anode and cathode lead 22 and 21 are respectively connected to N-type and P-type electrodes of the LED chip 10 via fine metal wires 24. The phosphor coating layer 23, and a molding layer 26 are located on the LED chip 20 in order. The phosphor coating layer 23 comprises the transparent resin and yellow phosphor.

When a height of the blue LED chip is 100 μm, the thickness of the yellow phosphor coating layer is 100 to 300 μm, which is one to three times as high as the height of the LED chip mounted in the recess portion. More preferably, the thickness of the yellow phosphor coating layer is 150 μm to 250 μm. If the thickness of the yellow phosphor coating layer is less than 100 μm, the insufficient coating on the surface of the LED chip makes it difficult to implement white color. If it exceed 300 μm, the light blocking and low energy efficiency reduce the light emitting property of the semiconductor light emitting device.

In accordance with the present invention, the yellow phosphor is applied in the upper side of the semiconductor light emitting device including the nitride semiconductor by selectively combining zinc selenium based red phosphor, and thus, white, blue-white, pink and pastel colors can be obtained by combining blue light of the semiconductor light emitting device, yellow light emitted by the yellow phosphor exposed to the blue light, and selectively red light of the red phosphor.

While the present invention has been described in detail with reference to the preferred embodiments, those skilled in the art will appreciate that various modifications and alterations can be made thereto without departing from the spirit and scope of the present invention as set forth in the appended claims.

As described above, a white, bluish white, pink, and pastel color light emitting diode containing the yellow phosphor and zinc selenium based red phosphor of the present invention absorbs a portion of light in the long wavelength UV region and in the visible light region emitted from a light emitting diode and emits yellow and red light. Therefore, it can be applied for red light emitting diode for a UV LED, white light emitting diode for blue, bluish white, pastel color, and pink light emitting diode, and such LED fields in which light of long wavelength UV and blue region is used as an energy source. Particularly, it is suitable as a back light source of LCDs since it has superior emission luminance and color rendering.

1. A yellow phosphor represented by the following chemical formula 1:
A_{(1-y)3}D₅₋ₓEₓO₁₂:Ce_{y} Chemical formula 1
wherein, A is at least one element selected from the group consisting of Y, Lu, Sc, La, Gd and Sm; D is at least one element selected from the group consisting of Al, Ga and In; E is at least one element selected from the group consisting of B and Fe; 0≦x<0.5; and 0.0001≦y<0.5.

2. The yellow phosphor according to claim 1, wherein the phosphor has an absorption peak ranging from about 420 nm to 480 nm, and an emission peak ranging from about 510 nm to 570 nm.

3. The yellow phosphor according to claim 1, wherein A is a mixture of Y and Gd.

4. The yellow phosphor according to claim 1, wherein the phosphor is of a spherical shape, and its mean diameter is 100 nm to 50 μm.

5. A white semiconductor light emitting device comprising:
a semiconductor light emitting diode; and
a phosphor coating layer comprising a yellow phosphor which absorbs a portion of light emitted by the semiconductor light emitting diode and emits light of wavelength different from that of the absorbed light and a transparent resin, where
the yellow phosphor is represented by the following chemical formula 1:
A_{(1-y)3}D₅₋ₓEₓO₁₂:Ce_{y} Chemical formula 1
wherein: A is at least one element selected from the group consisting of Y, Lu, Sc, La, Gd and Sm; D is at least one element selected from the group consisting of Al, Ga and In; E is at least one element selected from the group consisting of B and Fe; 0≦x<0.5; and 0.0001≦y<0.5;

6. The white semiconductor light emitting device according to claim 5, wherein the thickness of the phosphor coating layer (T₁) and the thickness of the semiconductor light emitting diode (T₂) meet the formula of T₂<T₁≦3T₂

7. The white semiconductor light emitting device according to claim 5, wherein the yellow phosphor contains phosphor with mean diameter of less than 1 μm in an amount of 0.01 to 10 wt %, and phosphor with mean diameter of 1 to 50 μm in an amount of 90 to 99.9 wt %.

8. The white semiconductor light emitting device according to claim 5, wherein the phosphor coating layer comprises a lower part including the phosphor with mean diameter of 1 to 50 μm, and a upper part including the phosphor with mean diameter of less than 1 μm.

9. The white semiconductor light emitting device according to claim 5, wherein the phosphor coating layer further comprises a zinc selenium-based red phosphor.

10. The white semiconductor light emitting device according to claim 9, wherein the amount of the zinc selenium-based red phosphor is 10 to 40 wt % based on the weight of the yellow phosphor.

11. The white semiconductor light emitting device according to claim 5, wherein the semiconductor light emitting diode comprises a substrate and a nitride semiconductor layer on the substrate.

12. The white semiconductor light emitting device according to claim 11, wherein the substrate is made of sapphire or silicone carbide.

13. The white semiconductor light emitting device according to claim 11, wherein the nitride semiconductor layer includes a GaN, InGaN, or AlGaInN-based semiconductor.

14. The white semiconductor light emitting device according to claim 5, wherein the transparent resin is a transparent epoxy resin or a silicone resin.

15. A lead type white semiconductor light emitting device comprising:
a mount lead comprising a lead and a recess portion on the lead;
a UV or a blue LED chip which is disposed in the recess portion, and an anode, a cathode of which are connected to the lead of the mount lead by metal wires;
a phosphor coating layer filled inside the recess portion to cover the LED chip; and
a casing that seals the mount lead excluding lower portions of the mount lead, the LED chip and phosphor coating layer,
wherein the phosphor coating layer comprises a transparent resin and a yellow phosphor represented by the following chemical formula 1:
A_{(1-y)3}D₅₋ₓEₓO₁₂:Ce_{y} Chemical formula 1
Wherein, A is at least one element selected from the group consisting of Y, Lu, Sc, La, Gd and Sm; D is at least one element selected from the group consisting of Al, Ga and In; E is at least one element selected from the group consisting of B and Fe; 0≦x<0.5; and 0.0001≦y<0.5;

16. The white semiconductor light emitting device according to claim 15, wherein the phosphor coating layer further comprises a zinc selenium-based red phosphor.

17. The white semiconductor light emitting device according to claim 15, which further comprises a transparent material layer between the semiconductor light emitting diode and the phosphor coating layer.

18. A lead type white semiconductor light emitting device comprising:
a casing with a recess portion on its top, and metal lead;
a UV and a blue LED chip which is disposed in the recess portion, and an anode and a cathode of which are connected to the lead by metal wires; and
a phosphor coating layer filled inside the recess portion to cover the LED chip,
wherein, the phosphor coating layer comprises a transparent resin and a yellow phosphor represented by the following chemical formula 1,
A_{(1-y)3}D₅₋ₓEₓO₁₂:Ce_{y} Chemical formula 1
wherein: A is at least one element selected from the group consisting of Y, Lu, Sc, La, Gd and Sm; D is at least one element selected from the group consisting of Al, Ga and In; E is at least one element selected from the group consisting of B and Fe; 0≦x<0.5; and 0.0001≦y<0.5;

19. The white semiconductor light emitting device according to claim 18, wherein the phosphor coating layer further comprises a zinc selenium-based red phosphor.

20. The white semiconductor light emitting device according to claim 18, which further comprises a transparent material layer between the semiconductor light emitting device and the phosphor coating layer.

21. The white semiconductor light emitting device according to claim 18, which further comprises a transparent molding layer on the phosphor coating layer.

22. A surface mount type white semiconductor light emitting device of the PCB (printed circuit board) type comprising a UV and blue LED chip and a phosphor coating layer formed orderly on a PCB layer, wherein the phosphor coating layer comprises yellow phosphor represented by the following chemical formula 1:
A_{(1-y)3}D₅₋ₓEₓO₁₂:Ce_{y} Chemical formula 1
Wherein, A is at least one element selected from the group consisting of Y, Lu, Sc, La, Gd and Sm; D is at least one element selected from the group consisting of Al, Ga and In; E is at least one element selected from the group consisting of B and Fe; 0≦x<0.5; and 0.0001≦y<0.5;

23. The white semiconductor light emitting device according to claim 22, wherein the phosphor coating layer further comprises a zinc selenium-based red phosphor.

24. The white semiconductor light emitting device according to claim 22, which further comprises a transparent molding layer on the phosphor coating layer.

25. A liquid crystal display incorporating the white semiconductor light emitting device according to any one of claims 5 as a back light source.
